(19) United States
(12) Patent Application Publication
(10) Pub. No.: US 2019/0079408 A1
(43) Pub. Date: Mar. 14, 2019

(54) DUAL DEVELOPING METHODS FOR LITHOGRAPHY PATTERNING

(71) Applicant: GLOBALFOUNDRIES INC., Grand Cayman (KY)

(72) Inventors: Sohan Singh Mehta, Saratoga Springs, NY (US); Mark C. Duggan, West Sand Lake, NY (US); Sunil Kumar Singh, Mechanicville, NY (US); Robert Justin Morgan, Clifton Park, NY (US); SherJang Singh, Clifton Park, NY (US); Ravi Prakash Srivastava, Clifton Park, NY (US); Craig D. Higgins, Altamont, NY (US); Jason L. Behnke, Galway, NY (US); Vineet Sharma, Mechanicville, NY (US)

(21) Appl. No.: 15/698,775

(22) Filed: Sep. 8, 2017

(51) Int. Cl. G03F 7/32

(52) U.S. Cl. CPC G03F 7/325; G03F 7/20

(57) ABSTRACT

The disclosure is directed to a method for lithographic patterning. The method may include: exposing a photoresist to a radiant energy; developing the photoresist in a first developer, thereby creating an opening within the photoresist including sidewalls having a slant; and developing the photoresist in a second developer immediately after the developing of the photoresist in the first developer, thereby reducing the slant of the sidewalls of the opening. Where the photoresist is a positive tone development (PTD) photoresist, the first developer may include a positive developer, and the second developer may include a negative developer. Where the photoresist is a negative tone development (NTD) photoresist, the first developer may include a negative developer, and the second developer may include a positive developer.

### BACKGROUND

### Technical Field

The present disclosure relates to methods of lithography patterning and, more specifically, the disclosure relates to developing a photoresist in a first developer immediately followed by developing the photoresist in a second developer.

### Related Art

In lithography (or “photolithography”), a radiation sensitive “photosensitive” is formed over one or more layers which are to be treated, in some manner, such as to be selectively doped and/or have a pattern transferred thereto. The resist is itself first patterned by exposing it to radiation, where the radiation (selectively) passes through an intervening mask or reticle containing the pattern. As a result, the exposed or unexposed areas of the photoresist become more or less soluble, depending on the type of photoresist used. A developer is then used to remove the more soluble areas of the resist leaving a patterned photoresist. The patterned photoresist can then serve as a mask for the underlying layers which can then be selectively treated, such as to undergo etching, for example.

A positive tone development (PTD) resist is a type of photoresist in which the portion of the photoresist that is exposed to light becomes soluble to the photoresist developer while the unexposed portion of the photoresist remains insoluble to the photoresist developer. A negative tone development (NTD) resist is a type of photoresist in which the portion of the photoresist that is exposed to light becomes insoluble to the photoresist developer while the unexposed portion of the photoresist is dissolved by the photoresist developer. As integrated circuit structures continue to scale down, conventional patterning processes for PTD and NTD resists suffer from poor depth of focus, defectivity, and reduced overlay performance. Additionally, the openings created during patterning of PTD and NTD resists after being developed include non-uniform critical dimensions.

For example, a critical dimension of an opening created during patterning can be determined by the focus used for the radiation and the type of developer. FIGS. 1 and 2 show a cross-section of an IC structure 1 after a prior art single developing process is used. In an example (FIG. 1), where an NTD resist 10 is exposed to a radiation with a negative focus (e.g., −40 nanometers (nm), −60 nm, −80, nm, etc.) and a developed in a negative developer, opening 12 may be formed being wider at the top of opening 12 than at the bottom of opening 12. That is, opening 12 may be wider proximate the top surface of NTD resist 10 than it is proximate the interface of NTD resist 10 and an underlying layer 16. This may result in bridging of openings proximate to one another. Additionally, NTD resists patterned with a negative focus generally do not completely develop. As a result, a portion of undeveloped NTD resist 10 may remain at the bottom of opening 12 over underlying layer 16. Therefore, it may be desirable to increase the focus in order to counter this effect. Where NTD resist 10 is exposed to a radiation with a positive focus (e.g., +40 nm, +60 nm, +80 nm, etc.) and developed in a negative developer, the patterned openings 12 (FIG. 2) may be wider at the bottom of opening 12 than at the top of opening 12. This problem may be referred to as “necking”. There may be some optimal focus determined by routine experimentation which may result in a critical dimension of the opening being substantially uniform, however, such optimal focus may not ensure complete development of the NTD resist where resist topography is uneven, e.g., where there is a “bump” (where the resist has a greater thickness in some areas over others) or where there is a “valley” (where the resist has a lesser thickness in some areas over others). This results in a portion of undeveloped NTD resist remaining at the bottom of the opening in those areas where there is a bump.

FIGS. 3 and 4 show a cross-section of an IC structure 2 after another prior art single developing process is used. In an example (FIG. 3), where a PTD resist 20 is exposed to a radiation with a positive focus (e.g., +40 nm, +60 nm, +80, nm, etc.) and developed in a positive developer, an opening 22 may be formed being wider at the top of opening 22 than at the bottom of opening 22. That is, opening 22 may be wider proximate the top surface of PTD resist 20 than proximate the interface of PTD resist 20 and an underlying layer 26. This may result in bridging of openings proximate to one another. Additionally, PTD resists patterned with a positive focus generally do not completely develop at the bottom. As a result, a portion of undeveloped resist 20 may remain at the bottom of opening 22 over underlying layer 26. Therefore, it may be desirable to decrease the focus in order to counter this effect. Where PTD resist 20 is exposed to a radiation with a negative focus (e.g., −40 nm, −60 nm, −80 nm, etc.) and developed in a positive developer, the patterned openings 22 may be wider at the bottom of opening 22 than at the top of opening 22. There may be some optimal focus determined by routine experimentation which may result in a critical dimension of the opening being substantially uniform, however, such optimal focus may not ensure complete development of the PTD resist where resist topography is uneven, e.g., where there is a bump or where there is a valley. This results in a portion of undeveloped PTD resist remaining at the bottom of the opening in those areas where there is a bump.

Prior dual develop techniques were designed to induce a resolution pitch split, but have not been used to improve patterning at exposure pitch. Additional conventional approaches include treating a surface of the resist, e.g., contacting the surface with a material, prior to developing the resist, but these techniques do not have sufficient polymer solubility to reduce bridging and necking.

### SUMMARY

A first aspect of the disclosure is directed to a method for lithographic patterning. The method may include: exposing a photoresist to a radiant energy; developing the photoresist in a first developer, thereby creating an opening in the photoresist, the opening including sidewalls having a slant; and developing the photoresist in a second developer immediately after the developing of the photoresist in the first developer, thereby reducing the slant of the sidewalls of the opening.

A second aspect of the disclosure is directed to a method for lithographic patterning. The method may include: exposing a positive tone development (PTD) photoresist to a radiant energy at a first focus through a mask; developing the PTD photoresist in a positive developer, thereby creating an opening within the PTD photoresist, the opening including sidewalls having a slant; and developing the PTD photoresist in a negative developer immediately after the developing of the PTD photoresist in the positive developer, thereby reducing the slant of the sidewalls of the opening.

A third aspect of the disclosure is directed to a method for lithographic patterning. The method may include: exposing a negative tone development (NTD) photoresist to a radiant energy at a first focus through a mask; developing the NTD photoresist in a negative developer, thereby creating an opening within the NTD photoresist, the opening including sidewalls having a slant; and exposing the NTD photoresist to a positive developer immediately after the exposing of the NTD photoresist to the negative developer, thereby reducing the slant of the sidewalls of the opening

The foregoing and other features of the disclosure will be apparent from the following more particular description of embodiments of the disclosure.

### BRIEF DESCRIPTION OF THE DRAWINGS

The embodiments of this disclosure will be described in detail, with reference to the following figures, wherein like designations denote like elements, and wherein:

FIGS. 1-4 show cross-sectional views of integrated circuit structures according to prior art single developing processes.

FIG. 5 shows a cross-sectional view of an integrated circuit structure including a positive tone development photoresist being exposed to radiant energy.

FIGS. 6-7 show a cross-sectional view of the integrated circuit structure of FIG. 5 after undergoing a positive developing process according to the disclosure, where FIG. 6 shows the integrated circuit structure after undergoing the positive developing process in a case where a positive focus was used for the radiant energy, and FIG. 7 shows the integrated circuit structure after undergoing the positive developing process in a case where a negative focus was used for the radiant energy.

FIG. 8 shows a cross-sectional view of the integrated circuit structure of FIGS. 6-7 after undergoing a negative developing process.

FIG. 9 shows a cross-sectional view of an integrated circuit structure including a negative tone development photoresist being exposed to radiant energy.

FIGS. 10-11 show a cross-sectional view of the integrated circuit structure of FIG. 9 undergoing a negative developing process according to the disclosure, where FIG. 10 shows the integrated circuit structure after undergoing the negative developing process in a case where a positive focus was used for the radiant energy, and FIG. 11 shows the integrated circuit structure after undergoing the negative developing process in a case where a negative focus was used for the radiant energy.

FIG. 12 shows a cross-sectional view of the integrated circuit structure of FIGS. 10-11 after undergoing a positive developing process.

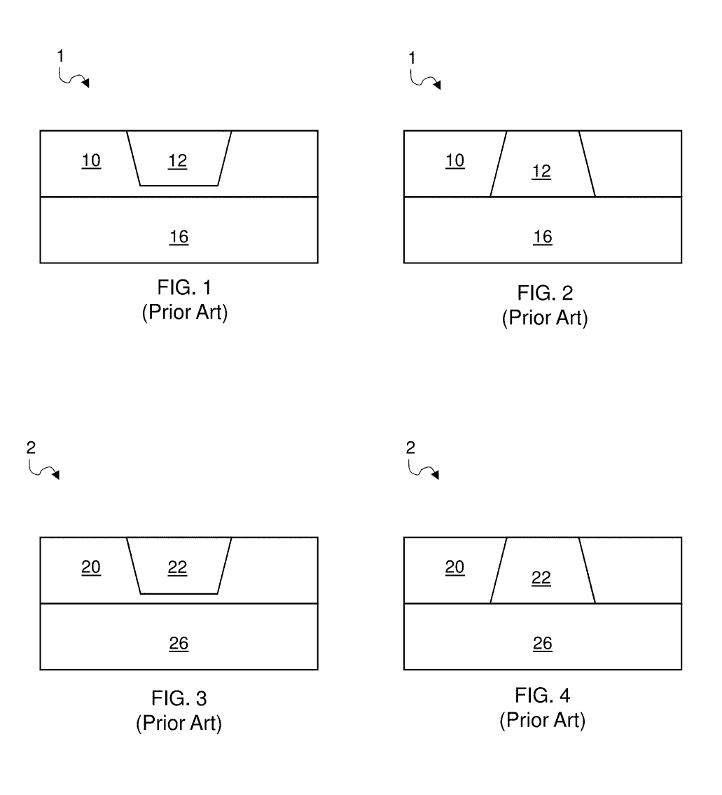

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

The present disclosure relates to methods of lithography patterning, more specifically, the disclosure relates to developing a photoresist in a first developer immediately followed by developing the photoresist in a second developer. In contrast to conventional methods of lithography patterning, the present disclosure provides methods which result in sidewalls of openings created within the patterned photoresist to be substantially parallel to one another such that each opening includes a uniform critical dimension. Further, the present disclosure does not merely treat a surface of a photoresist before developing the photoresist. Rather, the present disclosure provides for a dual developing process which improves the overall process window, and eliminates necking and bridging issues associated with using only a single developing process.

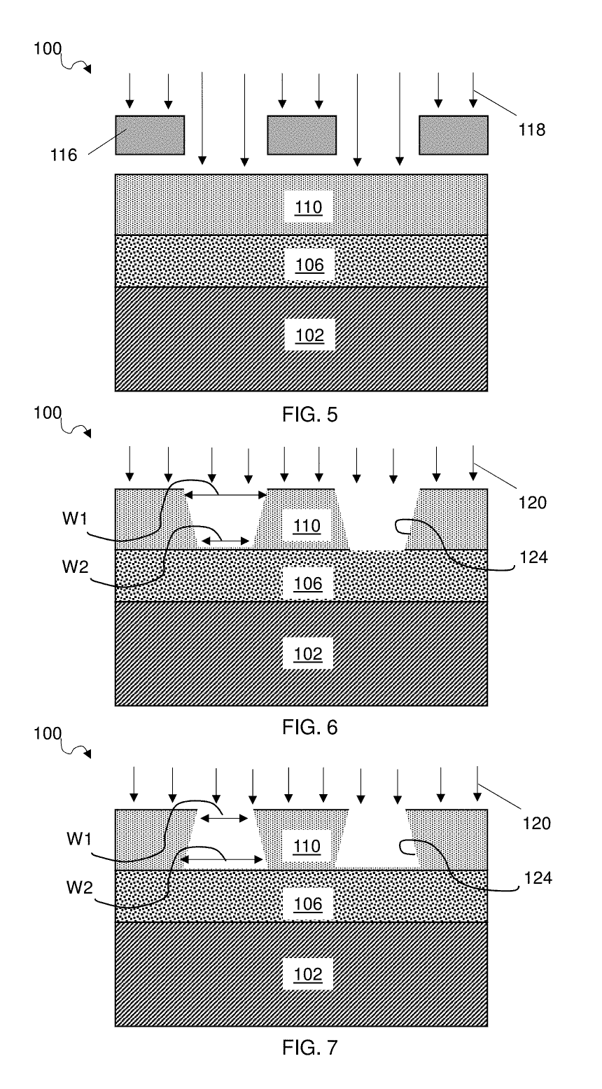

FIGS. 5-8 show cross-sectional views of a preliminary integrated circuit (IC) structure 100 undergoing aspects of a method according to embodiments of the disclosure. As shown in FIG. 5, IC structure 100 may include a substrate 102. Substrate 102 may include but is not limited to: silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, a portion or entirety of substrate 102 may be strained. While substrate 102 is shown as including a single layer of semiconductor material, it is emphasized that the teachings of the disclosure are equally applicable to semiconductor-on-insulator (SOI) substrates. As known in the art, SOI substrates may include a semiconductor layer on an insulator layer on another semiconductor layer (not shown). The semiconductor layers of an SOI substrate may include any of the semiconductor substrate materials discussed herein. The insulator layer of the SOI substrate may include any now known or later developed SOI substrate insulator such as but not limited to silicon oxide.

A film 106 may overlay substrate 102, and a photoresist 110 may overlay film 106. Film 106 may include any material, e.g., a semiconductor material or an insulator material, which it may be desired to transfer the pattern from photoresist 110 to. In this embodiment, photoresist 110 may include a positive tone development (PTD) photoresist. As shown in FIG. 5, a mask or reticle 116 including a desired pattern may be positioned over or somewhere above photoresist 110. Mask 116 may include a dark field mask. IC structure 100 may be exposed to a radiant energy 118, e.g., irradiated with light, to pattern photoresist 110. More specifically, photoresist 110 may be exposed to radiant energy 118 through mask 116. Some forms of radiant energy 118 may include any wavelength of ultraviolet (UV) light, as well as electron-beam (e-beam) and x-rays, to name a few. The focus of radiant energy 118 may include approximately −40 nm focus to approximately +40 nm focus. As known in the art, PTD photoresists are a type of photoresist in which the portion of the photoresist that is exposed to radiant energy becomes soluble to the photoresist developer. As a result, the portions of the photoresist 110 that are not covered by reticle 116 and are exposed to radiant energy 118 are soluble to the photoresist developers. The method may continue with developing patterned photoresist 110 in a first developer immediately followed by developing photoresist 110 in a second developer.

For example, as shown in FIG. 6, in a case where photoresist 110 is a PTD photoresist, photoresist 110 may first be developed in a first, positive developer 120, thereby creating an openings 124 within photoresist 110 including sidewalls having a slant. Positive developer 120 may include, for example, tetramethyl ammonium hydroxide. More specifically, in one example, positive developer 120 may include tetramethyl ammonium hydroxide in the amount of approximately equal to or greater than 0.26 molar equivalents per liter (N) in deionized water. Positive developer 120 may include any solvent developer or tetrabutyl ammonium hydroxide compromising the aforementioned normality ranges that substantially dissolves regions of the film that have been exposed to radiant energy 118 (FIG. 5). The duration of this positive developing process may be approximately 15 seconds to approximately 120 seconds, or more specifically, approximately 30 seconds to approximately 60 seconds. The developing of photoresist 110 in positive developer 120 may result in openings 124 being formed in photoresist 110. The width of openings 124 may be determined by the focus of radiant energy 118, the type of photoresist 110, and the type of developer used. More specifically, the focus used to expose photoresist 110 may be selected to ensure that photoresist 110 is completely developed within openings 124, i.e., such that no portion of photoresist 110 remains at the bottom of opening 124 and film 106 is exposed. Examples of such focus may include a range of: −40 nm to +40 nm. In an example, where a PTD resist is exposed to a radiation with a positive (e.g., +40 nm) and developed in a positive developer, openings may be formed being wider at the top of the opening, i.e., proximate the top of the PTD resist, than at the bottom of the opening, i.e., proximate the interface of the PTD resist and the underlying layer. Where the PTD resist is exposed to radiation with a negative focus (e.g., −40 nm) and developed in a positive developer, the patterned openings may be wider at the bottom of the opening, i.e., proximate the interface of the PTD resist and the underlying layer, than at the top of the opening, i.e., proximate the top of the PTD resist.

FIG. 6 shows an example where a positive focus (e.g., +40 nm) was used for radiant energy 118 (FIG. 5) and photoresist 110 is developed in positive developer 120. As shown, openings 124 may have an upper width W1 at a top of opening 124 that is wider or greater than a bottom width W2 at a bottom of opening 124. However, where a negative focus is used (e.g., −40 nm) for radiant energy 118, the reverse may be seen. For example, referring now to FIG. 7, where a negative focus (e.g., −40 nm) is used for the focus of radiant energy 118 (FIG. 5) and photoresist 110 is developed in positive developer 120, upper width W1 at the top of openings 124 may be less (e.g., smaller or more narrow) than bottom width W2 at the bottom of openings 124. In either embodiment, sidewalls of openings 124 may be noticeably, and sometimes substantially, slanted and not parallel to one another. As a result, each opening 124 may include a non-uniform critical dimension.

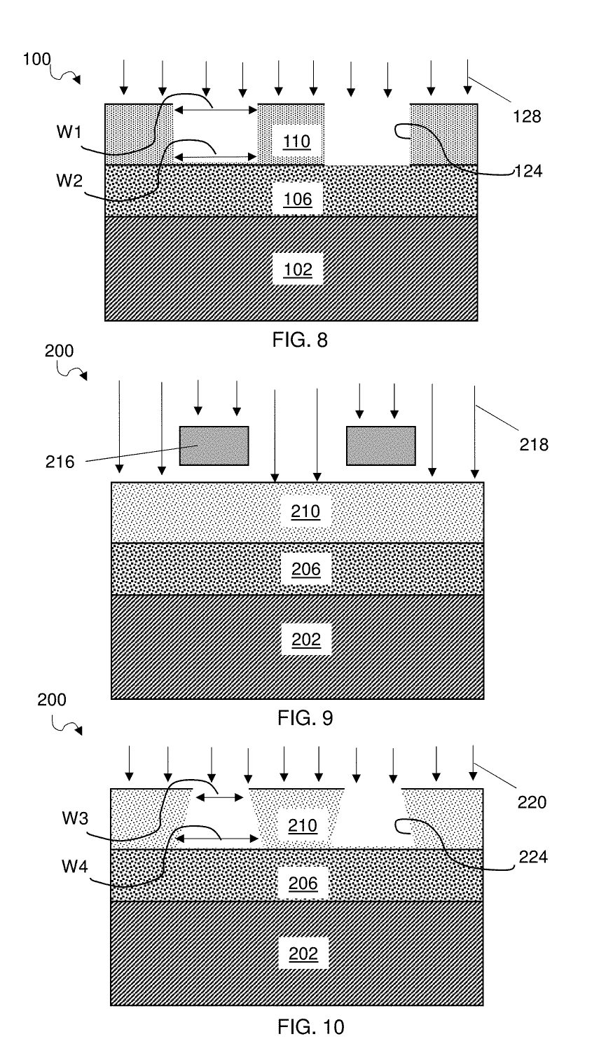

Turning now to FIG. 8, in either embodiment, photoresist 110 may be developed in a second, negative developer 128 immediately after being developed in the first, positive developer 120, thereby reducing the slant of sidewalls of openings 124. Negative developer 128 may include, for example, n-butyl acetate, methyl 2-hydroxybutyrate (HBM), propylene glycol monomethyl ether acetate (PGMEA), methyl isobutyl ketone, methyl isobutyl carbinol (MIBC), methoxyethoxypropionate, ethoxyethoxypropionate, gamma-butyrolactone, cyclohexanone, 2-heptanone, isoamyl acetate or a combination comprising at least one of the foregoing solvents. Negative developer 128 may include a solvent or solvent mixture that has a low dissolution rate of unexposed resist. Solvent polarity and/or base concentration properties may vary the dissolution rate to achieve the desired rates. The dissolution rate may range from approximately 0.008 Angstroms/second to approximately 3.0 Angstroms/second. For example, to achieve this desired dissolution rate, a concentration of 100% MIBC, 50% PGMS, 50% MIBC or a mixture of 30% MIBC, 30% PGMEA, and 40% HBM could be used. In another example, to achieve this desired dissolution rate, negative developer may include a Hansen solubility parameter for polarity ((hₚ or cal/cm³)_{1/2}) of approximately greater than 4.5. The duration of this negative developing process may be approximately 15 seconds to approximately 120 seconds, or more specifically, approximately 30 seconds to approximately 60 seconds. As a result of exposing photoresist 110 to negative developer 128 immediately after positive developer 120, width W1 and width W2 are about the same, and openings 124 have substantially parallel sidewalls and uniform critical dimensions. That is, the slant of the sidewalls of openings 124 becomes substantially reduced. More specifically, with reference to the embodiment of FIG. 6, i.e., where a positive focus (e.g., +40 nm) was used for radiant energy 118 (FIG. 5), the bottom of openings 124 become wider such that the difference between width W1 and W2 becomes less or width W1 and W2 are about the same. Additionally, with reference to the embodiment of FIG. 7, where a negative focus (e.g., −40 nm) was used for radiant energy 118 (FIG. 5), the top of openings 124 become wider such that width W1 and W2 becomes less different and/or are about the same. That is, by following a first developing process with a second developing process which includes a solvent having a dissolution rate of photoresist 110 of approximately 0.008 Angstroms/second to approximately 3.0 Angstroms/second, the slant of sidewalls of openings 124 substantially reduced without completely washing away photoresist 110. In some embodiments (shown), openings 124 have substantially parallel sidewalls and uniform critical dimensions without completely washing away photoresist 110. In this way, the second developing process controllably over-acts in order to create openings 124 having substantially parallel sidewalls, which may be substantially perpendicular to the top surface of film 106, and uniform critical dimensions.

FIGS. 9-12 show cross-sectional views of a preliminary integrated circuit (IC) structure 200 undergoing aspects of a method according to embodiments of the disclosure. As shown in FIG. 9, IC structure 200 may include a substrate 202. Overlying substrate 202 may be a film 206, and overlying film 206 may be photoresist 210. Substrate 202 and film 206 may include any of the substrate and film materials discussed relative to substrate 102 (FIG. 5) and film 106 (FIG. 5). In this embodiment, photoresist 210 may include a negative tone development (NTD) photoresist. As shown in FIG. 8, a mask or reticle 216 including a desired pattern may be positioned over photoresist 210. Mask 216 may include a bright field mask. IC structure 200 may be exposed to a radiant energy 218, e.g., irradiated with light, to pattern photoresist 210. More specifically, photoresist 210 may be exposed to radiant energy 218 through mask 216. Some forms of radiant energy 218 may include any wavelength of ultraviolet (UV) light, as well as electron-beam (e-beam) and x-rays, to name a few. The focus of radiant energy 218 may include approximately −40 nm focus to approximately +40 nm focus. As known in the art, NTD photoresists are a type of photoresist in which the portion of the photoresist that is exposed to radiant energy becomes insoluble to the photoresist developer. As a result, the portions of photoresist 210 that are covered by reticle 216 and not exposed to the radiant energy 218 are dissolved by the developers. The method may continue with developing patterned photoresist 210 in a first developer immediately followed by developing photoresist 210 in a second developer.

For example, as shown in FIG. 9, in a case where photoresist 210 is an NTD photoresist, photoresist 210 may first be developed in a first, negative developer 220 thereby creating an opening 224 within photoresist 210 including sidewalls having a slant. Negative developer 220 may include, for example, n-butyl acetate, methyl 2-hydroxybutyrate (HBM), propylene glycol monomethyl ether acetate (PGMEA), methyl isobutyl ketone, methyl isobutyl carbinol (MIBC), methoxyethoxypropionate, ethoxyethoxypropionate, gamma-butyrolactone, cyclohexanone, 2-heptanone, isoamyl acetate or a combination comprising at least one of the foregoing solvents. Negative developer 220 may include any solvent developer that substantially dissolves regions of the film that have not been exposed to radiant energy 218 (FIG. 8). In one example, negative developer may include a Hansen solubility parameter for polarity ((hₚ or (cal/cm³)_{1/2}) of approximately less than 4.5. The duration of this negative developing process may be approximately 15 seconds to approximately 120 seconds, or more specifically, approximately 30 seconds to approximately 60 seconds. The exposure of photoresist 210 to negative developer 220 may result in openings 224 being formed or defined in photoresist 210. The width of openings 224 may be determined by the focus of radiant energy 218, the type of photoresist 210, and the type of developer used. More specifically, the focus selected to develop photoresist 210 may result in non-uniform critical dimensions of openings 224 to ensure that photoresist 210 is completely developed within openings 224, i.e., such that no portion of photoresist 210 remains at the bottom of opening 224 and to expose film 206. Examples of such focus may include: −40 nm to +40 nm. In one example, where an NTD resist is exposed to a radiation with a negative focus (e.g., −40 nm) and developed in a negative developer, an opening may be formed being wider at the top of the opening, i.e., proximate the top surface of the NTD resist, than at the bottom of the opening, i.e., proximate the interface of the NTD resist and the underlying layer. Where the NTD resist is exposed to radiation with a positive focus (e.g., +40 nm) and developed in a negative developer, the patterned openings may be wider at the bottom of the opening, i.e., proximate the interface of the NTD resist and the underlying layer, than at the top of the opening, i.e., proximate a top surface of the NTD resist.

FIG. 10 shows an example where a positive focus (e.g., +40nm) was used for radiant energy 218 (FIG. 9) and photoresist 210 is developed in negative developer 220. As shown, openings 224 may have an upper width W3 at a top of openings 224 that is less (i.e., smaller or narrower) than a bottom width W4 at a bottom of openings 224. However, where a negative focus is used (e.g., −40 nm) for radiant energy 218, the reverse may be seen. For example, referring now to FIG. 11, where a negative focus (e.g., −40 nm) is used for the focus of radiant energy 218 (FIG. 9) and first developer 220 is a negative developer, upper width W3 at the top of openings 124 may be wider than bottom width W4 at the bottom of openings 224. In either embodiment, sidewalls of openings 224 may be noticeably and sometimes substantially slanted and not parallel to one another, and/or not perpendicular to the top surface of film 206.

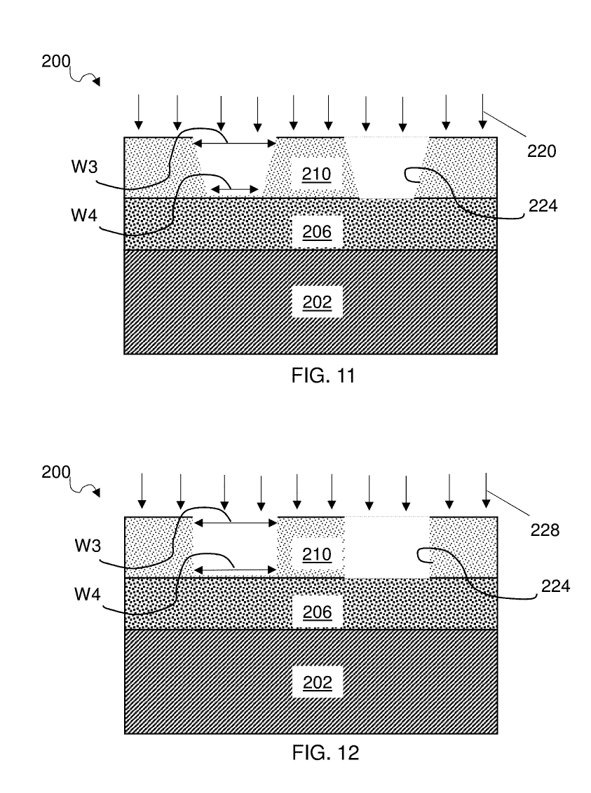

Turning now to FIG. 12, in either embodiment photoresist 210 may be developed in a second, positive developer 228 immediately after being developed in the first, negative developer 220 thereby reducing the slant of the sidewalls of openings 224. Positive developer 228 may include, for example, tetramethyl ammonium hydroxide. More specifically, in one example, positive developer 228 may include tetramethyl ammonium hydroxide in the amount of approximately less than 0.26 molar equivalents per liter (N) to approximately 0.000325 N in deionized water. Positive developer 120 may include any solvent developer or tetrabutyl ammonium hydroxide compromising the aforementioned normality ranges that substantially dissolves regions of the film that have been exposed to radiant energy 218 (FIG. 9). The dissolution rate may range from approximately 0.008 Angstroms/second to approximately 3.0 Angstroms/second. The duration of this positive developing process may be approximately 15 seconds to approximately 120 seconds, or more specifically, approximately 30 seconds to approximately 60 seconds. As a result of exposing photoresist 210 to positive developer 228 immediately after negative developer 220, width W3 and width W4 becomes less different and in one embodiment may become about the same, and openings 224 have substantially parallel sidewalls, substantially perpendicular to the top surface of film 206, and uniform critical dimensions. More specifically, with reference to the embodiment of FIG. 10, i.e., where a positive focus (e.g., +40 nm) was used for radiant energy 218 (FIG. 9), the top of openings 224 become wider such that the difference between width W3 and W4 becomes less, and in one embodiment width W3 and W4 are about the same. Additionally, with reference to the embodiment of FIG. 11, where a negative focus (e.g., −40 nm) was used for radiant energy 218 (FIG. 9), the bottom of openings 224 become wider such that width W3 and W4 becomes less different and in some embodiment may become about the same. That is, by following a first developing process with a second developing process which includes a solvent having a dissolution rate of photoresist 210 of approximately 0.008 Angstroms/second to approximately 3.0 Angstroms/second, the slant of sidewalls of openings 224 substantially reduces without completely washing away photoresist 210. In some embodiments (shown), openings 224 have substantially parallel sidewalls and uniform critical dimensions. In this way, the second developing process controllably over-acts in order to create openings 224 having substantially parallel sidewalls and uniform critical dimensions, and the sidewalls may become substantially perpendicular to the top surface of underneath film, i.e., film 206.

The dual developing process of the present disclosure provides for patterned openings having uniform critical dimensions. In this way, the openings created after the dual development process include substantially parallel sidewalls. As a result, the present disclosure overcomes the problems of bridging and necking that conventional lithographic processes face and the overall process window of the resists is improved. The present disclosure utilizes the opposite developing nature of PTD and NTD resists at any focus such that when one is followed by the other, and the second developing process includes a dissolution rate of the photoresist of approximately 0.008 Angstroms/second to approximately 3.0 Angstroms/second, uniform openings are achieved. It is to be understood that the present disclosure is equally applicable to any type of lithography process, electron beam lithography, nanoimprint lithography, interference lithography, X-ray lithography, extreme ultraviolet lithography, magnetolithography and scanning probe lithography, etc.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s). “Substantially” refers to largely, for the most part, entirely specified or any slight deviation which provides the same technical benefits of the disclosure.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A method for lithographic patterning, the method comprising:
exposing a photoresist to a radiant energy;
developing the photoresist in a first developer, thereby creating an opening in the photoresist, the opening including sidewalls having a slant; and
developing the photoresist in a second developer immediately after the developing of the photoresist in the first developer, thereby reducing the slant of the sidewalls of the opening.

2. The method of claim 1, wherein the second developer includes a dissolution rate of the photoresist of approximately 0.008 Angstroms/second to approximately 3.0 Angstroms/second.

3. The method of claim 1, wherein the photoresist is a positive tone development (PTD) photoresist, the first developer is a positive developer, and the second developer is a negative developer.

4. The method of claim 3, wherein the negative developer includes at least one of: n-butyl acetate, methyl 2-hydroxybutyrate (HBM), propylene glycol monomethyl ether acetate (PGMEA), methyl isobutyl ketone, methyl isobutyl carbinol (MIBC), methoxyethoxypropionate, ethoxyethoxypropionate, gamma-butyrolactone, cyclohexanone, 2-heptanone, isoamyl acetate, and the positive developer includes tetramethyl ammonium hydroxide.

5. The method of claim 3, wherein the positive developer includes a concentration of approximately equal to or greater than 0.26 molar equivalents per liter (N) in deionized water, and wherein the negative developer includes a Hansen solubility parameter for polarity of approximately greater than 4.5.

6. The method of claim 1, wherein the photoresist is a negative tone development (NTD) photoresist, the first developer is a negative developer, and the second developer is a positive developer.

7. The method of claim 6, wherein the negative developer includes at least one of: n-butyl acetate, methyl 2-hydroxybutyrate (HBM), propylene glycol monomethyl ether acetate (PGMEA), methyl isobutyl ketone, methoxyethoxypropionate, ethoxyethoxypropionate, gamma-butyrolactone, cyclohexanone, 2-heptanone, or isoamyl acetate, and the positive developer includes tetramethyl ammonium hydroxide.

8. The method of claim 6, wherein the positive developer includes a concentration of approximately less than 0.26 N to approximately 0.000325 N in deionized water, and the negative developer includes a Hansen solubility parameter for polarity of approximately less than 4.5.

9. A method for lithographic patterning, the method comprising:
exposing a positive tone development (PTD) photoresist to a radiant energy at a first focus through a mask;
developing the PTD photoresist in a positive developer, thereby creating an opening within the PTD photoresist, the opening including sidewalls having a slant; and
developing the PTD photoresist in a negative developer immediately after the developing of the PTD photoresist in the positive developer, thereby reducing the slant of the sidewalls of the opening.

10. The method of claim 9, wherein the negative developer includes at least one of: n-butyl acetate, methyl 2-hydroxybutyrate (HBM), propylene glycol monomethyl ether acetate (PGMEA), methyl isobutyl ketone, methoxyethoxypropionate, ethoxyethoxypropionate, gamma-butyrolactone, cyclohexanone, 2-heptanone, or isoamyl acetate, and the positive developer includes tetramethyl ammonium hydroxide.

11. The method of claim 10, wherein the positive developer includes a concentration of approximately equal to or greater than 0.26 molar equivalents per liter (N) in deionized water, and wherein the negative developer includes a Hansen solubility parameter for polarity of approximately greater than 4.5.

12. The method of claim 9, wherein the first focus is a positive focus, and the exposing the PTD photoresist to the positive developer includes creating the opening having an upper width greater than a bottom width of the opening.

13. The method of claim 9, wherein the first focus is a negative focus, and the exposing the PTD photoresist to the positive developer includes defining the opening having an upper width less than a bottom width of the opening.

14. The method of claim 9, wherein the negative developer has a dissolution rate of the PTD photoresist of approximately 0.008 Angstroms/second to approximately 3.0 Angstroms/second.

15. A method for lithographic patterning, the method comprising:
exposing a negative tone development (NTD) photoresist to a radiant energy at a first focus through a mask;
developing the NTD photoresist in a negative developer, thereby creating an opening within the NTD photoresist, the opening including sidewalls having a slant; and
exposing the NTD photoresist to a positive developer immediately after the exposing of the NTD photoresist to the negative developer, thereby reducing the slant of the sidewalls of the opening.

16. The method of claim 15, wherein the negative developer includes at least one of: n-butyl acetate, methyl 2-hydroxybutyrate (HBM), propylene glycol monomethyl ether acetate (PGMEA), methyl isobutyl ketone, methoxyethoxypropionate, ethoxyethoxypropionate, gamma-butyrolactone, cyclohexanone, 2-heptanone, or isoamyl acetate, and the positive developer includes tetramethyl ammonium hydroxide.

17. The method of claim 16, wherein the positive developer includes a concentration of approximately less than 0.26 molar equivalents per liter (N) to approximately 0.000325 N in deionized water, and wherein and the negative developer includes a Hansen solubility parameter for polarity of approximately less than 4.5.

18. The method of claim 15, wherein the first focus is a positive focus, and the exposing the NTD photoresist to the negative developer includes defining the opening having an upper width less than a bottom width of the opening.

19. The method of claim 15, wherein the first focus is a negative focus, and the exposing the NTD photoresist to the negative developer includes creating the opening having an upper width greater than a bottom width of the opening.

20. The method of claim 15, wherein the positive developer has a dissolution rate of the NTD photoresist of approximately 0.008 Angstroms/second to approximately 3.0 Angstroms/second.
